(19) United States
(12) Patent Application Publication
(10) Pub. No.: US 2014/0060573 A1
(43) Pub. Date: Mar. 6, 2014

(54) SUBSTRATE TREATMENT METHOD AND SUBSTRATE TREATMENT APPARATUS

(71) Applicant: DAINIPPON SCREEN MFG.CO.,LTD., Kyoto (JP)

(72) Inventor: Yukifumi YOSHIDA, Kyoto (JP)

(73) Assignee: DAINIPPON SCREEN MFG. CO., LTD., Kyoto (JP)

(21) Appl. No.: 13/961,923

(22) Filed: Aug. 8, 2013

(30) Foreign Application Priority Data
Aug. 28, 2012 (JP) 2012-188009

(51) Int. Cl. H01L 21/02

(52) U.S. Cl. CPC H01L 21/02082
USPC 134/1.3; 134/105

(57) ABSTRACT

A substrate treatment method for removing a resist from a front surface of a substrate is provided. The method includes: a liquid mixture film forming step of forming a liquid film of a liquid mixture of a sulfuric acid-containing liquid and an organic solvent on a front surface of a substrate held by a substrate holding unit; and an infrared radiation applying step of providing a heater in opposed relation to the front surface of the substrate and applying infrared radiation emitted from the heater to the front surface of the substrate on which the liquid film of the liquid mixture is retained.

### BACKGROUND OF THE INVENTION

1. Field of the Invention

The present invention relates to a substrate treatment method and a substrate treatment apparatus for treating a substrate such as a semiconductor wafer with a sulfuric acid-containing liquid.

2. Description of Related Art

A semiconductor device production process, for example, includes the step of locally implanting an impurity such as phosphorus, arsenic or boron (ions) into a front surface of a semiconductor wafer (hereinafter referred to simply as “wafer”). In order to prevent the ion implantation in an unnecessary portion of the wafer, a resist pattern of a photosensitive resin is formed on the front surface of the wafer to mask the unnecessary portion of the wafer with the resist in this step. After the ion implantation, the resist pattern formed on the front surface of the wafer becomes unnecessary and, therefore, a resist removing process is performed for removing the unnecessary resist.

In a typical example of the resist removing process, the front surface of the wafer is irradiated with oxygen plasma to ash the resist on the front surface of the wafer. Then, a chemical liquid such as a sulfuric acid/hydrogen peroxide mixture (SPM liquid: a liquid mixture of sulfuric acid and a hydrogen peroxide aqueous solution) is supplied to the front surface of the wafer to remove the asked resist. Thus, the resist is removed from the front surface of the wafer.

However, the irradiation with the oxygen plasma for the ashing of the resist damages a portion of the front surface of the wafer uncovered with the resist (e.g., an oxide film exposed from the resist).

Therefore, a method of lifting off the resist from the front surface of the wafer by the strong oxidative power of peroxomonosulfuric acid (H₂SO₅) contained in the SPM liquid supplied onto the front surface of the wafer without ashing the resist has recently been attracting attention. (see, for example, JP2005-32819A1).

### SUMMARY OF THE INVENTION

Where the wafer is subjected to a higher-dose ion implantation, however, the resist is liable to be altered (hardened).

One exemplary method for imparting the SPM liquid with a higher resist removing capability is that the temperature of the SPM liquid present on the front surface of the wafer is increased to a higher temperature (e.g., not lower than 200° C.) With this method, a resist even having a hard layer on its surface can be removed from the front surface of the wafer without the ashing.

A conceivable method for maintaining a portion of the SPM liquid adjacent to an interface between the SPM liquid and the front surface of the wafer at the higher temperature is to continuously supply a higher temperature SPM liquid to the wafer W. However, this may increase the consumption of the SPM liquid.

The inventor of the present invention contemplates that a heater having an infrared lamp is provided in opposed relation to the front surface of the wafer, and infrared radiation emitted from the heater is applied to a liquid film of the SPM liquid covering the entire front surface of the wafer to heat the SPM liquid. This method makes it possible to remove the hardened resist from the wafer while reducing the consumption of the SPM liquid. In addition, this remarkably increases the resist removing efficiency, thereby reducing the resist removing process time.

However, the infrared absorbance of the SPM liquid is not so high. The infrared radiation emitted from the heater passes through the SPM liquid film, and is absorbed by the silicon wafer. More specifically, the wafer is warmed earlier than the SPM liquid, and then the SPM liquid film is heated by the wafer. That is, the SPM liquid film heating efficiency is supposedly lower. If the infrared absorbance of the SPM liquid film can be increased in this case, the SPM liquid film heating efficiency can be increased to more advantageously warm the SPM liquid film.

It is therefore an object of the present invention to provide a substrate treatment method and a substrate treatment apparatus which ensure that a liquid film of a sulfuric acid-containing liquid covering the entire front surface of a substrate can be more advantageously warmed.

The present invention provides a substrate treatment method for removing a resist from a front surface of a substrate, the method including: a liquid mixture film forming step of forming a liquid film of a liquid mixture of a sulfuric acid-containing liquid and an organic solvent on a front surface of a substrate held by a substrate holding unit; and an infrared radiation applying step of providing a heater in opposed relation to the front surface of the substrate, and applying infrared radiation emitted from the heater to the front surface of the substrate on which the liquid film of the liquid mixture is retained.

In this method, the liquid film of the liquid mixture of the sulfuric acid-containing liquid and the organic solvent is formed on the front surface of the substrate. In the liquid mixture of the sulfuric acid-containing liquid and the organic solvent, particles of black carbides are precipitated, so that the liquid mixture is entirely black. The precipitated black carbide particles are mostly constituted by carbon and, hence, have a very high infrared absorbance. Therefore, the liquid film of the liquid mixture of the sulfuric acid-containing liquid and the organic solvent has a higher infrared absorbance and, hence, has a higher heating efficiency. By thus forming the liquid film of the liquid mixture on the front surface of the substrate, the liquid mixture containing the sulfuric acid-containing liquid can be more advantageously warmed in the infrared radiation applying step. This further increases the process efficiency for the resist removing process, thereby reducing the process time required for the entire resist removing process.

The black carbides are supposedly precipitated by the following generation mechanism. When the organic solvent reacts with sulfuric acid in the sulfuric acid-containing liquid, the organic solvent is dehydrated to generate an ether, an ester and the like. Then, the ether and the ester thus generated are further carbonized by sulfuric acid in the sulfuric acid-containing liquid, whereby the resulting black carbides are precipitated.

Examples of the organic solvent include an IPA liquid, ethanol, acetone and other organic solvents which are carbonized by the dehydration and oxidation action of sulfuric acid.

In an embodiment of the present invention, the liquid mixture film forming step includes an organic solvent liquid film forming step of forming a liquid film of the organic solvent on the front surface of the substrate held by the substrate holding unit, and a sulfuric acid-containing liquid supplying step of supplying the sulfuric acid-containing liquid to the front surface of the substrate retaining the liquid film of the organic solvent after the organic solvent liquid film forming step.

In this method, the sulfuric acid-containing liquid is supplied to the front surface of the substrate on which the liquid film of the organic solvent is formed.

In this case, the sulfuric acid-containing liquid is supplied to a greater amount of the organic solvent and, therefore, a reaction occurring due to the mixing and the contact of the sulfuric acid-containing liquid and the organic solvent is moderate as compared with a case in which the organic solvent is supplied to a greater amount of the sulfuric acid-containing liquid. This prevents a violent reaction from occurring due to the contact and the mixing of the sulfuric acid-containing liquid and the organic solvent.

In another embodiment of the present invention, the liquid mixture film forming step includes a sulfuric acid-containing liquid film forming step of forming a liquid film of the sulfuric acid-containing liquid on the front surface of the substrate held by the substrate holding unit, and an organic solvent supplying step of supplying the organic solvent to the front surface of the substrate retaining the liquid film of the sulfuric acid-containing liquid after the sulfuric acid-containing liquid film forming step.

In this method, the organic solvent is supplied to the front surface of the substrate on which the liquid film of the sulfuric acid-containing liquid is formed. In this case, the amount of the sulfuric acid is greater than the amount of the organic solvent, so that a dehydration reaction reliably proceeds.

The substrate treatment method may include a cleaning step of cleaning the front surface of the substrate held by the substrate holding unit (by using a cleaning chemical liquid) after the infrared radiation applying step.

After the infrared radiation applying step, the liquid mixture of the sulfuric acid-containing liquid and the organic solvent is removed from the front surface of the substrate but, if the black carbide particles remain on the front surface of the substrate after the removal of the liquid mixture, the particles may contaminate the substrate.

In this method, the front surface of the substrate is cleaned after the infrared radiation applying step. Therefore, the black carbide particles are not present on the front surface of the substrate after the cleaning step. As a result, occurrence of particles can be prevented.

The present invention also provides a substrate treatment apparatus for removing a resist from a front surface of a substrate, the apparatus including: a substrate holding unit which holds the substrate; a liquid mixture supplying unit which supplies a liquid mixture of a sulfuric acid-containing liquid and an organic solvent to form a liquid film of the liquid mixture of the sulfuric acid-containing liquid and the organic solvent on the front surface of the substrate held by the substrate holding unit; and a heater having an infrared lamp and provided in opposed relation to the front surface of the substrate held by the substrate holding unit to irradiate the front surface of the substrate with infrared radiation.

With this arrangement, the liquid film of the liquid mixture of the sulfuric acid-containing liquid and the organic solvent is formed on the front surface of the substrate. In the liquid mixture of the sulfuric acid-containing liquid and the organic solvent, particles of black carbides are precipitated, so that the liquid mixture is entirely black. The precipitated black carbide particles are mostly constituted by carbon and, hence, have a very high infrared absorbance. Therefore, the liquid film of the liquid mixture of the sulfuric acid-containing liquid and the organic solvent has a higher infrared absorbance and, hence, has a higher heating efficiency. By thus forming the liquid film of the liquid mixture on the front surface of the substrate, the liquid mixture containing the sulfuric acid-containing liquid can be more advantageously warmed. This further increases the process efficiency of the resist removing process, thereby reducing the process time required for the entire resist removing process.

The black carbides are precipitated supposedly because of the following generation mechanism. When the organic solvent reacts with sulfuric acid in the sulfuric acid-containing liquid, the organic solvent is dehydrated to generate an ether, an ester and the like. Then, the ether and the ester thus generated are further carbonized by sulfuric acid in the sulfuric acid-containing liquid, whereby the resulting black carbides are precipitated.

Examples of the organic solvent include an IPA liquid, ethanol, acetone and other organic solvents which are carbonized by the dehydration and oxidation action of sulfuric acid.

In an embodiment of the present invention, the liquid mixture supplying unit includes a sulfuric acid-containing liquid nozzle which spouts the sulfuric acid-containing liquid to the front surface of the substrate held by the substrate holding unit, and an organic solvent nozzle which spouts the organic solvent to the front surface of the substrate held by the substrate holding unit.

With this arrangement, the sulfuric acid-containing liquid is spouted from the sulfuric acid-containing liquid nozzle to the front surface of the substrate. Further, the organic solvent is spouted from the organic solvent nozzle to the front surface of the substrate. Thus, the liquid film of the liquid mixture of the sulfuric acid-containing liquid and the organic solvent can be advantageously formed on the front surface of the substrate.

There is a possibility that a violent reaction occurs due to the contact and the mixing of the sulfuric acid-containing liquid and the organic solvent. However, the reaction does not occur within a pipe or the like, but occurs on the front surface of the substrate, because the sulfuric acid-containing liquid and the organic solvent are mixed together on the front surface of the substrate. Therefore, the substrate treatment apparatus is free from heavy damage.

In this case, the organic solvent nozzle may be a spray nozzle which sprays liquid droplets of the organic solvent. With this arrangement, the organic solvent liquid droplets are sprayed from the organic solvent nozzle. Where the organic solvent liquid droplets are sprayed onto the front surface of the substrate with the sulfuric acid-containing liquid film formed on the front surface of the substrate, the organic solvent liquid droplets can be extensively and evenly supplied to the sulfuric acid-containing liquid film.

Since the organic solvent liquid droplets are minute liquid droplets, a violent reaction is substantially prevented from occurring due to the contact and the mixing of the sulfuric acid-containing liquid and the organic solvent.

In another embodiment of the present invention, the liquid mixture supplying unit includes a liquid mixture nozzle which spouts the liquid mixture of the sulfuric acid-containing liquid and the organic solvent to the front surface of the substrate held by the substrate holding unit.

With this arrangement, the liquid mixture of the sulfuric acid-containing liquid and the organic solvent is spouted from the liquid mixture nozzle. Therefore, the liquid film of the liquid mixture of the sulfuric acid-containing liquid and the organic solvent can be advantageously formed on the front surface of the substrate.

The foregoing and other objects, features and effects of the present invention will become more apparent from the following detailed description of the preferred embodiments with reference to the attached drawings.

### BRIEF DESCRIPTION OF THE DRAWINGS

FIG. 1 is a diagram schematically showing the construction of a substrate treatment apparatus according to an embodiment of the present invention.

FIG. 2 is a schematic sectional view of a heater head shown in FIG. 1.

FIG. 3 is a perspective view of an infrared lamp shown in FIG. 2.

FIG. 4 is a perspective view of a combination of a heater arm and the heater head shown in FIG. 1.

FIG. 5 is a plan view showing positions of the heater head shown in FIG. 1.

FIG. 6 is a block diagram showing the electrical construction of the substrate treatment apparatus shown in FIG. 1.

FIG. 7 is a process diagram showing a first exemplary resist removing process to be performed by the substrate treatment apparatus shown in FIG. 1.

FIG. 8 is a time chart for explaining control operations to be performed by a controller in major steps of the first exemplary process.

FIG. 9A is a schematic diagram for explaining a step of the first exemplary process.

FIG. 9B is a schematic diagram showing a step subsequent to the step of FIG. 9A.

FIG. 9C is a schematic diagram showing a step subsequent to the step of FIG. 9B.

FIG. 9D is a schematic diagram showing a step subsequent to the step of FIG. 9C.

FIG. 10 is a diagram showing a black carbide generation mechanism.

FIG. 11 is a process diagram for explaining a second exemplary process to be performed by the substrate treatment apparatus shown in FIG. 1.

FIG. 12A is a schematic diagram for explaining a step of the second exemplary process.

FIG. 12B is a schematic diagram showing a step subsequent to the step of FIG. 12A.

FIG. 13 is a schematic diagram showing a modification of the second exemplary process.

FIG. 14 is a process diagram for explaining a third exemplary process to be performed by the substrate treatment apparatus shown in FIG. 1.

FIG. 15 is a process diagram for explaining a fourth exemplary process to be performed by the substrate treatment apparatus shown in FIG. 1.

FIG. 16 is a diagram schematically showing the construction of a substrate treatment apparatus according to another embodiment of the present invention.

FIG. 17 is a process diagram for explaining an exemplary process to be performed by the substrate treatment apparatus shown in FIG. 16.

### DETAILED DESCRIPTION OF PREFERRED EMBODIMENTS

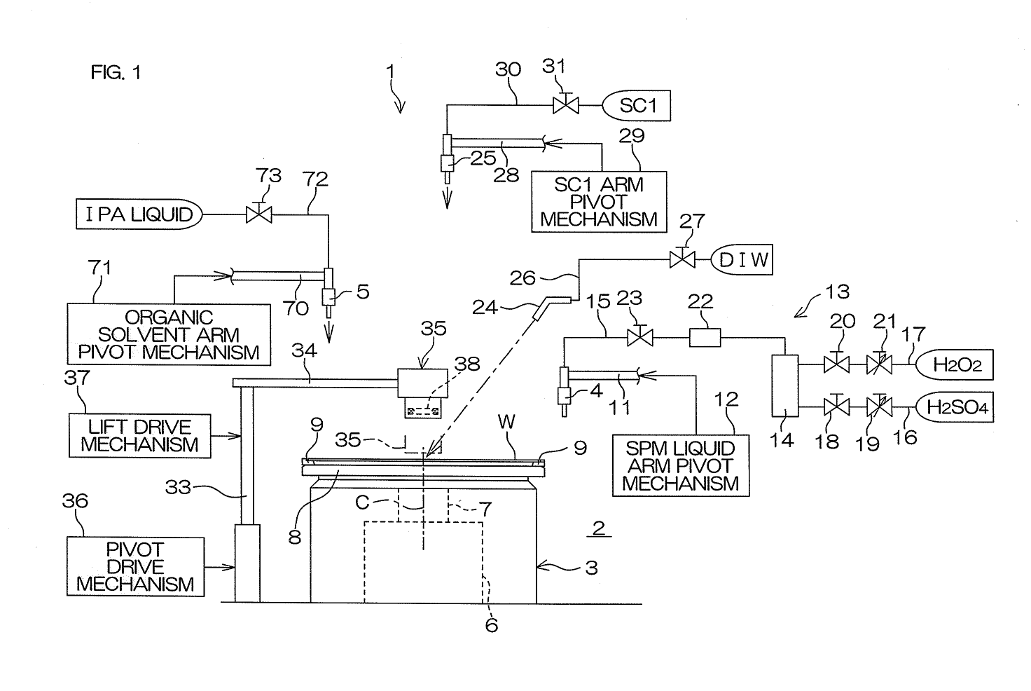

FIG. 1 is a diagram schematically showing the construction of a substrate treatment apparatus 1 which performs a substrate treatment method according to one embodiment of the present invention. The substrate treatment apparatus 1 is an apparatus of a single wafer treatment type to be used, for example, in a resist removing process for removing an unnecessary resist from a front surface of a wafer W (an example of a substrate) after an ion implantation process for implanting an impurity into the front surface of the wafer W or after a dry etching process.

The substrate treatment apparatus 1 includes a treatment chamber 2 defined by a partition wall (not shown), a wafer rotating mechanism (substrate holding unit) 3 which holds and rotates the wafer W, an SPM liquid nozzle (sulfuric acid-containing liquid nozzle) 4 which supplies an SPM liquid (sulfuric acid/hydrogen peroxide mixture as an example of a sulfuric acid-containing liquid) to the front surface (upper surface) of the wafer W held by the wafer rotating mechanism 3, an organic solvent nozzle 5 which supplies an IPA liquid (isopropyl alcohol as an example of an organic solvent) to the front surface (upper surface) of the wafer W held by the wafer rotating mechanism 3, and a heater head (heater) 35 to be located in opposed relation to the front surface of the wafer W held by the wafer rotating mechanism 3 for emitting infrared radiation to the front surface of the wafer W. The wafer rotating mechanism 3, the SPM liquid nozzle 4, the organic solvent nozzle 5 and the heater head 35 are disposed in the treatment chamber 2.

The wafer rotating mechanism 3 is of a clamping type. More specifically, the wafer rotating mechanism 3 includes, for example, a motor 6, a spin shaft 7 unitary with a drive shaft of the motor 6, a disk-shaped spin base 8 horizontally attached to an upper end of the spin shaft 7, and a plurality of clamping members 9 generally equiangularly arranged on a peripheral edge portion of the spin base 8. The wafer W is clamped by the clamping members 9 in a generally horizontal attitude. When the motor 6 is driven in this state, the spin base 8 is rotated about a rotation axis (vertical axis) C by a driving force of the motor 6, and the wafer W is rotated in the generally horizontal attitude together with the spin base 8 about the rotation axis C.

The wafer rotating mechanism 3 is not limited to the clamping type, but may be of a vacuum suction type, which is rotated about the rotation axis C while horizontally holding the wafer W by sucking a back surface of the wafer W by vacuum to thereby rotate the wafer W thus held.

The SPM liquid nozzle 4 is, for example, a straight nozzle which spouts the SPM liquid in the form of a continuous stream. The SPM liquid nozzle 4 is attached to a distal end of a generally horizontally extending SPM liquid arm 11 with its outlet port directing downward. The SPM liquid arm 11 is pivotal about a predetermined pivot axis extending vertically. An SPM liquid arm pivot mechanism 12 which pivots the SPM liquid arm 11 within a predetermined angular range is connected to the SPM liquid arm 11. By the pivoting of the SPM liquid arm 11, the SPM liquid nozzle 4 is moved between a position defined on the rotation axis C of the wafer W (a position at which the SPM liquid nozzle 4 is opposed to the rotation center of the wafer W) and a home position defined on a lateral side of the wafer rotating mechanism 3.

An SPM liquid supplying mechanism 13 which supplies the SPM liquid to the SPM liquid nozzle 4 includes a first mixing portion 14 which mixes sulfuric acid (H₂SO₄) and a hydrogen peroxide solution (H₂O₂) together, and an SPM liquid supply pipe 15 connected between the first mixing portion 14 and the SPM liquid nozzle 4. A sulfuric acid supply pipe 16 and a hydrogen peroxide solution supply pipe 17 are connected to the first mixing portion 14. Sulfuric acid temperature-controlled at a predetermined temperature (e.g., about 80° C.) is supplied to the sulfuric acid supply pipe 16 from a sulfuric acid supply source (not shown) to be described later. On the other hand, a hydrogen peroxide solution not temperature-controlled but having a temperature equivalent to a room temperature (about 25° C.) is supplied to the hydrogen peroxide solution supply pipe 17 from a hydrogen peroxide solution supply source (not shown). A sulfuric acid valve 18 and a flow rate control valve 19 are provided in the sulfuric acid supply pipe 16. Further, a hydrogen peroxide solution valve 20 and a flow rate control valve 21 are provided in the hydrogen peroxide solution supply pipe 17. A stirring flow pipe 22 and an SPM liquid valve 23 are provided in this order from the first mixing portion 14 in the SPM liquid supply pipe 15. The stirring flow pipe 22 includes, for example, a pipe member, and a plurality of stirring fins of rectangular plates which are each twisted approximately 180 degrees about an axis extending in a liquid flow direction and arranged along a pipe center axis extending in the liquid flow direction in the pipe member with their twist angular positions alternately offset by 90 degrees about the pipe center axis.

When the sulfuric acid valve 18 and the hydrogen peroxide solution valve 20 are opened with the SPM liquid valve 23 open, the sulfuric acid supplied from the sulfuric acid supply pipe 16 and the hydrogen peroxide solution supplied from the hydrogen peroxide solution supply pipe 17 flow into the first mixing portion 14, and flow out of the first mixing portion 14 into the SPM liquid supply pipe 15. The sulfuric acid and the hydrogen peroxide solution pass through the stirring flow pipe 22 to be sufficiently stirred while flowing through the SPM liquid supply pipe 15. The sulfuric acid and the hydrogen peroxide solution sufficiently react with each other by the stirring in the stirring flow pipe 22. Thus, the SPM liquid is prepared which contains a great amount of peroxomonosulfuric acid (H₂SO₅). The heat of the reaction between the sulfuric acid and the hydrogen peroxide solution elevates the temperature of the SPM liquid to a higher temperature (130° C. to 170° C., e.g., about 140° C.) that is not lower than the liquid temperature of the sulfuric acid supplied to the first mixing portion 14. The higher-temperature SPM liquid is supplied to the SPM liquid nozzle 4 through the SPM liquid supply pipe 15.

The organic solvent nozzle 5 is, for example, a straight nozzle which spouts the IPA liquid in the form of a continuous stream. The organic solvent nozzle 5 is attached to a distal end of a generally horizontally extending organic solvent arm 70 with its outlet port directing downward. The organic solvent arm 70 is pivotal about a predetermined pivot axis extending vertically. An organic solvent arm pivot mechanism 71 which pivots the organic solvent arm 70 within a predetermined angular range is connected to the organic solvent arm 70. By the pivoting of the organic solvent arm 70, the organic solvent nozzle 5 is moved between a position defined on the rotation axis C of the wafer W (a position at which the organic solvent nozzle 5 is opposed to the rotation center of the wafer W) and a home position defined on a lateral side of the wafer rotating mechanism 3.

An organic solvent supply pipe 72 to which the IPA liquid is supplied from an IPA liquid supply source is connected to the organic solvent nozzle 5. An organic solvent valve 73 which switches on and off the supply of the IPA liquid from the organic solvent nozzle 5 is provided in the organic solvent supply pipe 72.

The substrate treatment apparatus 1 includes a rinse liquid nozzle 24 which supplies DIW (deionized water as a rinse liquid) to the front surface of the wafer W held by the wafer rotating mechanism 3, and an SC1 nozzle 25 which supplies SC1 (ammonia/hydrogen peroxide mixture as a cleaning chemical liquid) to the front surface of the wafer W held by the wafer rotating mechanism 3.

The rinse liquid nozzle 24 is, for example, a straight nozzle which spouts the DIW in the form of a continuous stream, and is fixed above the wafer rotating mechanism 3 with its outlet port directing toward around the rotation center of the wafer W. A rinse liquid supply pipe 26 to which the DIW is supplied from a DIW supply source is connected to the rinse liquid nozzle 24. A rinse liquid valve 27 which switches on and off the supply of the DIW from the rinse liquid nozzle 24 is provided in the rinse liquid supply pipe 26.

The SC1 nozzle 25 is, for example, a straight nozzle which spouts the SC1 in the form of a continuous stream. The SC1 nozzle 25 is attached to a distal end of a generally horizontally extending SC1 arm 28 with its outlet port directing downward. The SC1 arm 28 is pivotal about a predetermined pivot axis extending vertically. An SC1 arm pivot mechanism 29 which pivots the SC1 arm 28 within a predetermined angular range is connected to the SC1 arm 28. By the pivoting of the SC1 arm 28, the SC1 nozzle 25 is moved between a position defined on the rotation axis C of the wafer W (a position at which the SC1 nozzle 25 is opposed to the rotation center of the wafer W) and a home position defined on a lateral side of the wafer rotating mechanism 3.

An SC1 supply pipe 30 to which the SC1 is supplied from an SC1 supply source is connected to the SC1 nozzle 25. An SC1 valve 31 which switches on and off the supply of the SC1 from the SC1 nozzle 25 is provided in the SC1 supply pipe 30.

A vertically extending support shaft 33 is disposed on a lateral side of the wafer rotating mechanism 3. A horizontally extending heater arm 34 is connected to an upper end of the support shaft 33, and a heater head 35 is attached to a distal end of the heater arm 34. The support shaft 33 is connected to a pivot drive mechanism 36 which rotates the support shaft 33 about its center axis, and a lift drive mechanism 37 which moves up and down the support shaft 33 along its center axis.

A drive force is inputted from the pivot drive mechanism 36 to the support shaft 33 to rotate the support shaft 33 within a predetermined angular range, whereby the heater arm 34 is pivoted about the support shaft 33 above the wafer W held by the wafer rotating mechanism 3. By the pivoting of the heater arm 34, the heater head 35 is moved between a position defined on the rotation axis C of the wafer W (a position at which the heater head 35 is opposed to the rotation center of the wafer W) and a home position defined on a lateral side of the wafer rotating mechanism 3. Further, a drive force is inputted from the lift drive mechanism 37 to move up and down the support shaft 33, whereby the heater head 35 is moved up and down between a position adjacent to the front surface of the wafer W held by the wafer rotating mechanism 3 (a position indicated by a two-dot-and-dash line in FIG. 1, and including a middle adjacent position, an edge adjacent position and a center adjacent position to be described later) and a retracted position above the wafer W (a position indicated by a solid line in FIG. 1).

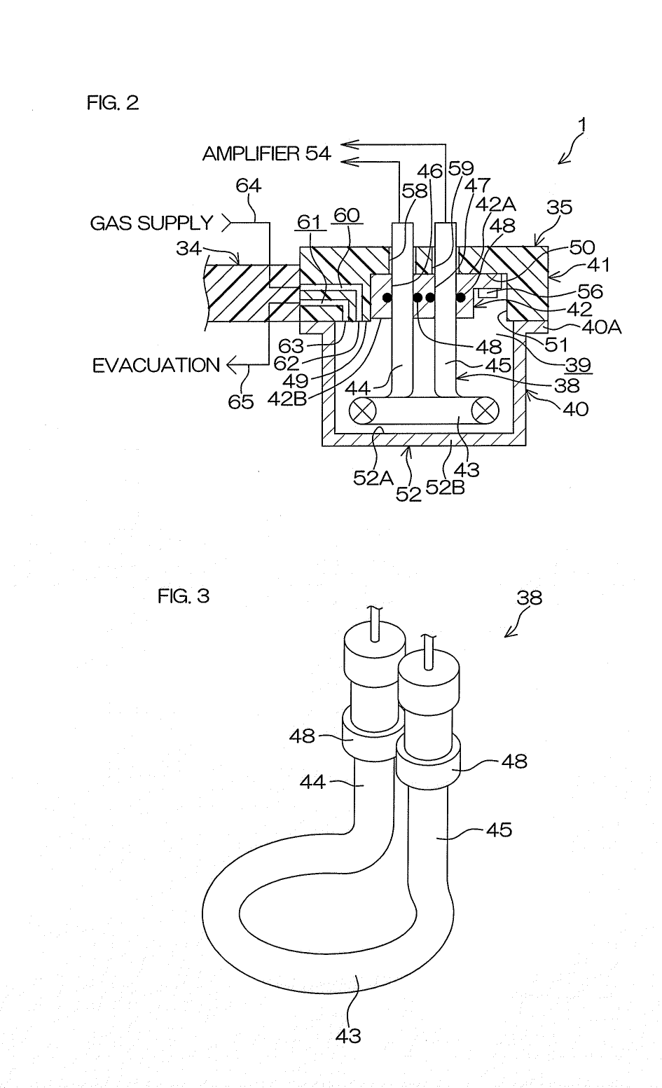

FIG. 2 is a schematic sectional view of the heater head 35.

The heater head 35 includes an infrared lamp 38, a lamp housing 40 which is a bottomed container having a top opening 39 and accommodating the infrared lamp 38, a support member 42 which supports and suspends the infrared lamp 38 in the lamp housing 40, and a lid 41 which closes the opening 39 of the lamp housing 40. In this embodiment, the lid 41 is fixed to the distal end of the heater arm 34.

FIG. 3 is a perspective view of the infrared lamp 38.

As shown in FIGS. 2 and 3, the infrared lamp 38 is a unitary infrared lamp heater which includes an annular portion 43 having an annular shape (arcuate shape), and a pair of straight portions 44, 45 extending vertically upward from opposite ends of the annular portion 43 along a center axis of the annular portion 43. The annular portion 43 mainly functions as a light emitting portion which emits infrared radiation. In this embodiment, the annular portion 43 has a diameter (outer diameter) of, for example, about 60 mm. With the infrared lamp 38 supported by the support member 42, the center axis of the annular portion 43 vertically extends. In other words, the center axis of the annular portion 43 is perpendicular to the front surface of the wafer W held by the wafer rotating mechanism 3. The infrared lamp 38 is disposed in a generally horizontal plane.

The infrared lamp 38 includes a quartz tube, and a filament accommodated in the quartz tube. Typical examples of the infrared lamp 38 include infrared heaters of shorter wavelength, intermediate wavelength and longer wavelength such as halogen lamps and carbon heaters. An amplifier 54 for voltage supply is connected to the infrared lamp 38.

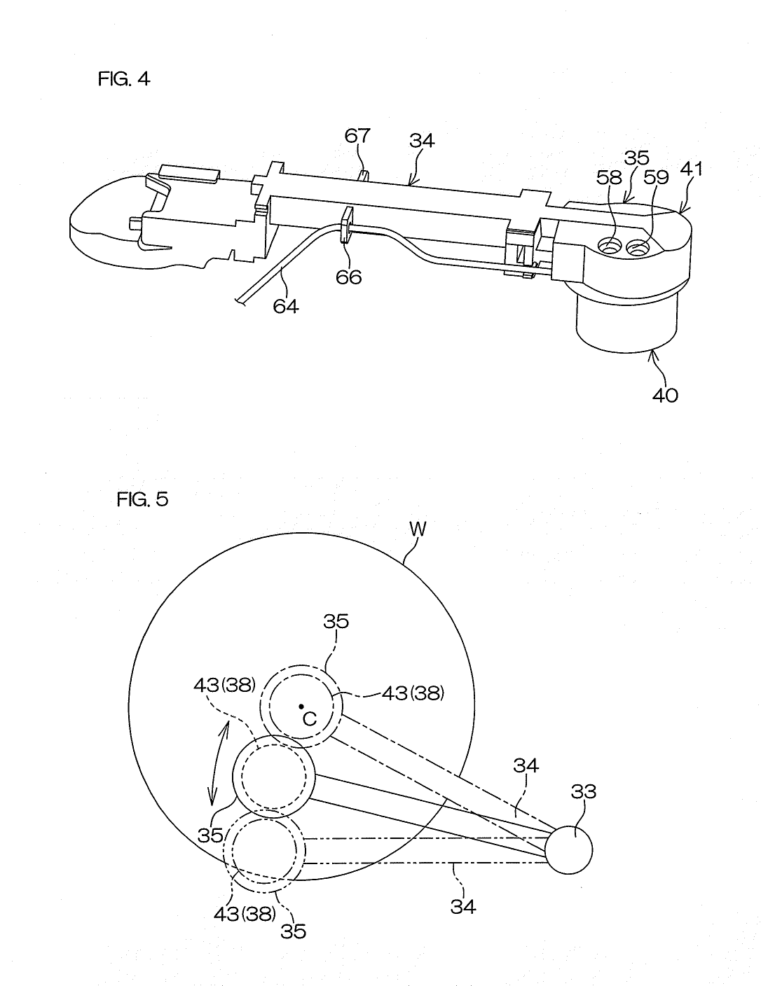

FIG. 4 is a perspective view of a combination of the heater arm 34 and the heater head 35.

As shown in FIGS. 2 and 4, the lid 41 has a disk shape, and is fixed to the heater arm 34 as extending longitudinally from the heater arm 34. The lid 41 is formed of a fluororesin such as PTFE (polytetrafluoroethylene). In this embodiment, the lid 41 is formed integrally with the heater arm 34. However, the lid 41 may be formed separately from the heater arm 34. Exemplary materials for the lid 41 other than resin materials such as PTFE include ceramic materials and quartz.

As shown in FIG. 2, a (generally cylindrical) groove 51 is provided in a lower surface 49 of the lid 41. The groove 51 has a horizontal flat upper base surface 50, and an upper surface 42A of the support member 42 is fixed to the upper base surface 50 in contact with the upper base surface 50. As shown in FIGS. 2 and 4, the lid 41 has insertion holes 58, 59 extending vertically through the upper base surface 50 and a lower surface 42B. Upper end portions of the straight portions 44, 45 of the infrared lamp 38 are respectively inserted in the insertion holes 58, 59. In FIG. 4, the heater head 35 is illustrated with the infrared lamp 38 removed from the heater head 35.

As shown in FIG. 2, the lamp housing 40 of the heater head 35 is a bottomed cylindrical container. The lamp housing 40 is formed of quartz.

The lamp housing 40 of the heater head 35 is fixed to the lower surface 49 of the lid 41 (to a portion of the lower surface 49 of the lid 41 not formed with the groove 51 in this embodiment) with its opening 39 facing up. An annular flange 40A projects radially outward (horizontally) from a peripheral edge of the opening of the lamp housing 40. The flange 40A is fixed to the lower surface 49 of the lid 41 with a fixture unit such as bolts (not shown), whereby the lamp housing 40 is supported by the lid 41.

A bottom plate 52 of the lamp housing 40 has a horizontal disk shape. The bottom plate 52 has an upper surface 52A and a lower surface 52B which are horizontal flat surfaces. In the lamp housing 40, a lower portion of the annular portion 43 of the infrared lamp 38 is located in closely opposed relation to the upper surface 52A of the bottom plate 52. The annular portion 43 and the bottom plate 52 are parallel to each other. In other words, the lower portion of the annular portion 43 is covered with the bottom plate 52 of the lamp housing 40. In this embodiment, the lamp housing 40 has an outer diameter of, for example, about 85 mm. Further, a vertical distance between the lower end of the infrared lamp 38 (the lower portion of the annular portion 43) and the upper surface 52A is, for example, about 2 mm.

The support member 42 is a thick plate having a generally disk shape. The support member 42 is horizontally attached and fixed to the lid 41 from below by bolts 56 or the like. The support member 42 is formed of a heat-resistant material (e.g., a ceramic or quartz). The support member 42 has two insertion holes 46, 47 extending vertically through the upper surface 42A and the lower surface 42B thereof. The straight portions 44, 45 of the infrared lamp 38 are respectively inserted in the insertion holes 46, 47.

O-rings are respectively fixedly fitted around intermediate portions of the straight portions 44, 45. With the straight portions 44, 45 respectively inserted in the insertion holes 46, 47, outer peripheries of the respective O-rings 48 are kept in press contact with inner walls of the insertion holes 46, 47. Thus, the straight portions 44, 45 are prevented from being withdrawn from the insertion holes 46, 47, whereby the infrared lamp 38 is suspended to be supported by the support member 42.

When electric power is supplied to the infrared lamp 38 from the amplifier 54, the infrared lamp 38 emits infrared radiation, which is in turn outputted through the lamp housing 40 downward of the heater head 35. In the resist removing process to be described later, the bottom plate 52 of the lamp housing 40 which defines a lower end face of the heater head 35 is located in opposed relation to the front surface of the wafer W held by the wafer rotating mechanism 3. In this state, the infrared radiation outputted through the bottom plate 52 of the lamp housing 40 heats the wafer W and the SPM liquid present on the wafer W. Since the annular portion 43 of the infrared lamp 38 assumes a horizontal attitude, the infrared radiation can be evenly applied onto the front surface of the wafer W horizontally held. Thus, the wafer W and the SPM liquid present on the wafer W can be efficiently irradiated with the infrared radiation.

In the heater head 35, the periphery of the infrared lamp 38 is covered with the lamp housing 40. The flange 40A of the lamp housing 40 and the lower surface 49 of the lid 41 are kept in intimate contact with each other circumferentially of the lamp housing 40. Further, the opening 39 of the lamp housing 40 is closed by the lid 41. Thus, an atmosphere containing droplets of the SPM liquid around the front surface of the wafer W is prevented from entering the lamp housing 40 and adversely influencing the infrared lamp 38 in the resist removing process to be described later. Further, the SPM liquid droplets are prevented from adhering onto the quartz tube wall of the infrared lamp 38, so that the amount of the infrared radiation emitted from the infrared lamp 38 can be kept stable for a longer period of time.

The lid 41 includes a gas supply passage 60 through which air is supplied into the lamp housing 40, and an evacuation passage 61 through which an internal atmosphere of the lamp housing 40 is expelled. The gas supply passage 60 and the evacuation passage 61 respectively have a gas supply port 62 and an evacuation port 63 which are open in the lower surface of the lid 41. The gas supply passage 60 is connected to one of opposite ends of a gas supply pipe 64. The other end of the gas supply pipe 64 is connected to an air supply source. The evacuation passage 61 is connected to one of opposite ends of an evacuation pipe 65. The other end of the evacuation pipe 65 is connected to an evacuation source.

While air is supplied into the lamp housing 40 from the gas supply port 62 through the gas supply pipe 64 and the gas supply passage 60, the internal atmosphere of the lamp housing 40 is expelled to the evacuation pipe 65 through the evacuation port 63 and the evacuation passage 61. Thus, a higher-temperature atmosphere in the lamp housing 40 can be expelled for ventilation. Thus, the inside of the lamp housing 40 can be cooled. As a result, the infrared lamp 38 and the lamp housing 40, particularly the support member 42, can be advantageously cooled.

As shown in FIG. 4, the gas supply pipe 64 and the evacuation pipe 65 (not shown in FIG. 4, but see FIG. 2) are respectively supported by a plate-shaped gas supply pipe holder 66 provided on one side face of the heater arm 34 and a plate-shaped evacuation pipe holder 67 provided on the other side face of the heater arm 34.

FIG. 5 is a plan view showing positions of the heater head 35.

The pivot drive mechanism 36 and the lift drive mechanism 37 are controlled to move the heater head 35 along an arcuate path crossing a wafer rotating direction above the front surface of the wafer W.

When the wafer W and the SPM liquid present on the wafer W are heated by the infrared lamp 38 of the heater head 35, the heater head 35 is located at the adjacent position at which the bottom plate 52 (lower end face) thereof is opposed to and spaced a minute distance (e.g., 3 mm) from the front surface of the wafer W. During the heating, the bottom plate 52 (lower surface 52B) and the front surface of the wafer W are kept spaced the minute distance from each other.

Examples of the adjacent position of the heater head 35 include a middle adjacent position (indicated by a solid line in FIG. 5), an edge adjacent position (indicated by a two-dot-and-dash line in FIG. 5) and a center adjacent position (indicated by a one-dot-and-dash line in FIG. 5).

With the heater head 35 located at the middle adjacent position, the center of the round heater head 35 as seen in plan is opposed to a radially intermediate portion of the front surface of the wafer W (a portion intermediate between the position defined on the rotation axis C and a peripheral edge portion of the wafer W), and the bottom plate 52 of the heater head 35 is spaced the minute distance (e.g., 3 mm) from the front surface of the wafer W.

With the heater head 35 located at the edge adjacent position, the center of the round heater head 35 as seen in plan is opposed to the peripheral edge portion of the front surface of the wafer W, and the bottom plate 52 of the heater head 35 is spaced the minute distance (e.g., 3 mm) from the front surface of the wafer W.

With the heater head 35 located at the center adjacent position, the center of the round heater head 35 as seen in plan is opposed to the position of the front surface of the wafer W defined on the rotation axis C, and the bottom plate 52 of the heater head 35 is spaced the minute distance (e.g., 3 mm) from the front surface of the wafer W.

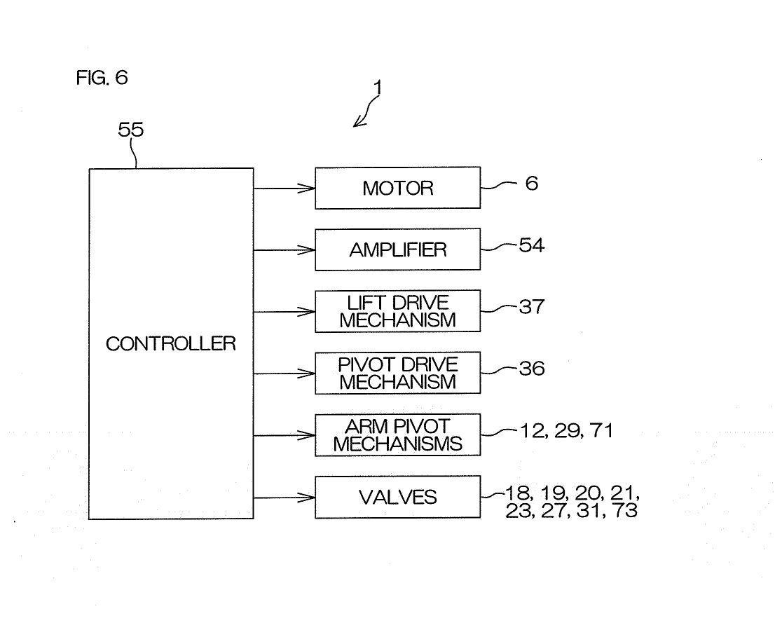

FIG. 6 is a block diagram showing the electrical construction of the substrate treatment apparatus 1. The substrate treatment apparatus 1 includes a controller 55 having a configuration including a microcomputer. The controller 55 is connected to the motor 6, the amplifier 54, the pivot drive mechanism 36, the lift drive mechanism 37, the SPM liquid arm pivot mechanism 12, the SC1 arm pivot mechanism 29, the organic solvent arm pivot mechanism 71, the sulfuric acid valve 18, the hydrogen peroxide solution valve 20, the SPM liquid valve 23, the rinse liquid valve 27, the SC1 valve 31, the organic solvent valve 73, the flow rate control valves 19, 21, and the like, which are controlled by the controller 55.

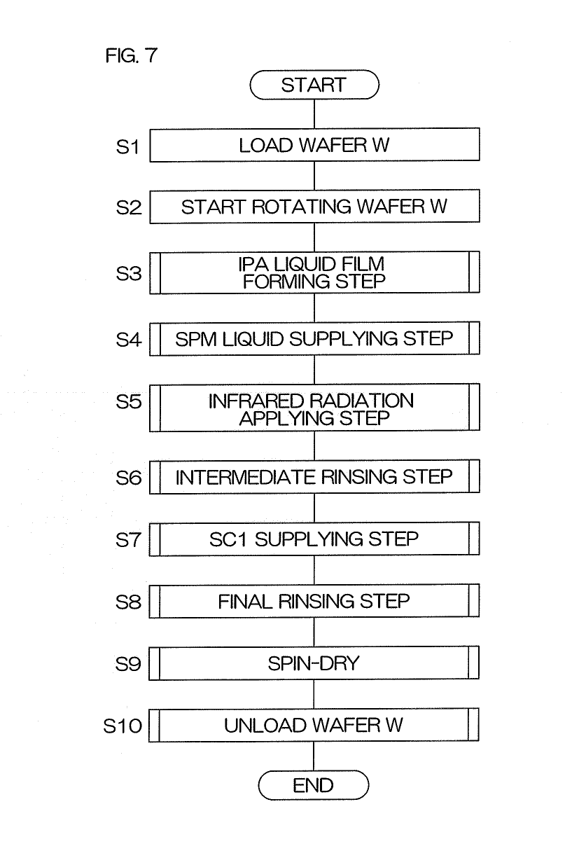

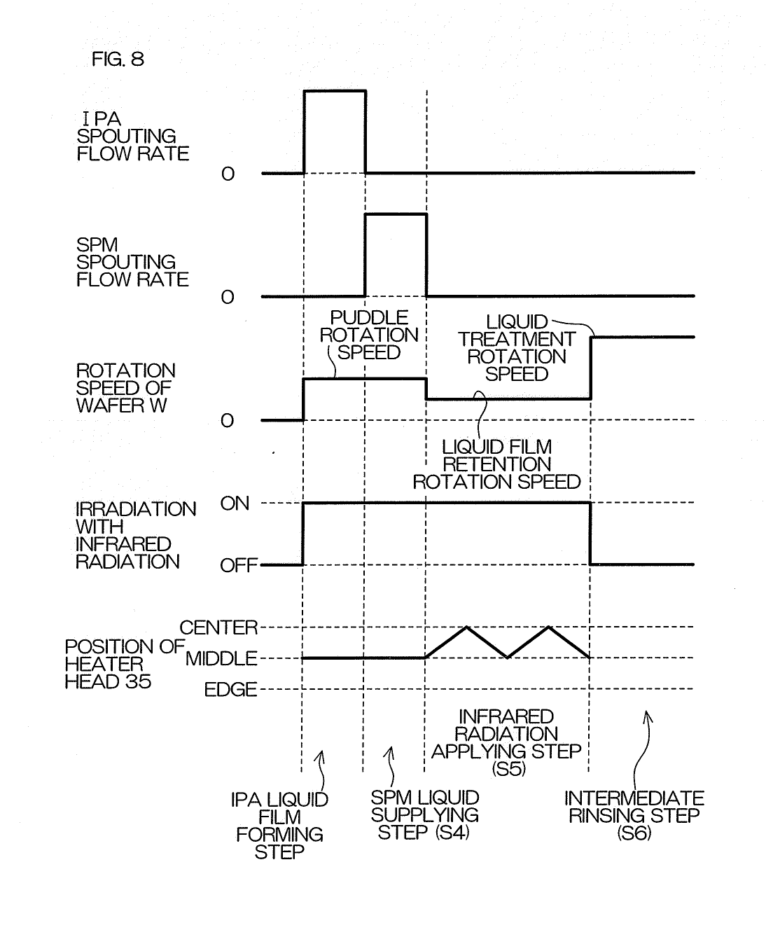

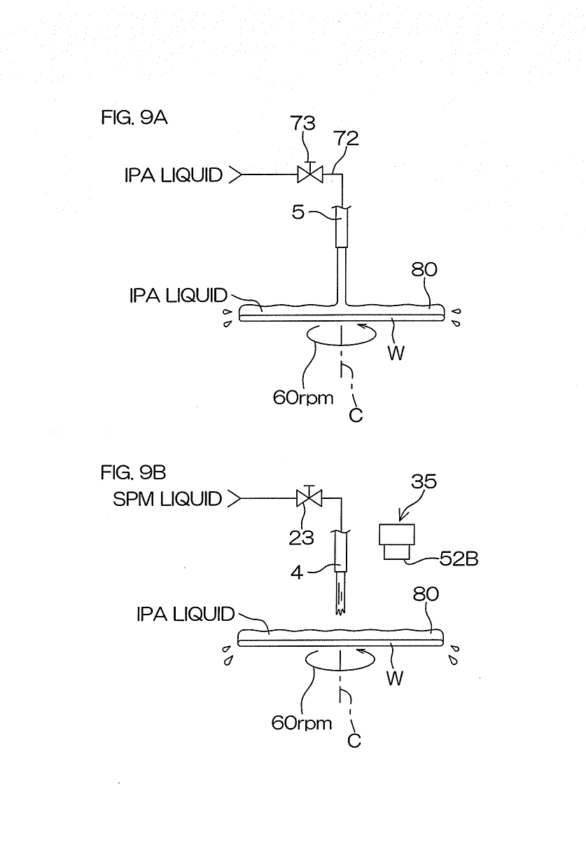

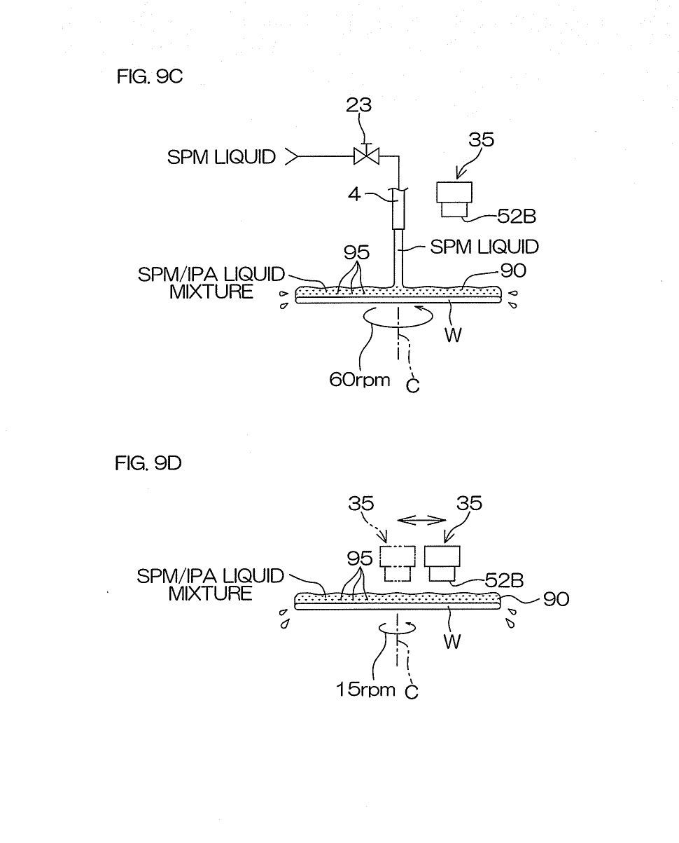

FIG. 7 is a process diagram showing a first exemplary resist removing process to be performed by the substrate treatment apparatus 1. FIG. 8 is a time chart for explaining control operations to be performed by the controller 55 in an IPA liquid film forming step of Step S3, an SPM liquid supplying step of Step S4, and an infrared radiation applying step of Step S5. FIGS. 9A to 9D are schematic diagrams for explaining the IPA liquid film forming step, the SPM liquid supplying step and the infrared radiation applying step.

Referring to FIGS. 1 to 9D, the first exemplary resist removing process will be described.

In the resist removing process, a transport robot (not shown) is controlled to load a wafer W subjected to the ion implantation process into the treatment chamber 2 (see FIG. 1) (Step S1: wafer loading step). It is herein assumed that the wafer W is not subjected to a resist aching process. The wafer W is transferred to the wafer rotating mechanism 3 with its front surface facing up. At this time, the heater head 35, the SPM liquid nozzle 4, the organic solvent nozzle 5 and the SC1 nozzle 25 are located at their home positions so as not to hinder the loading of the wafer W.

With the wafer W held by the wafer rotating mechanism 3, the controller 55 controls the motor 6 to start rotating the wafer W (Step S2). The rotation speed of the wafer W is increased to a predetermined puddle rotation speed, and then maintained at the puddle rotation speed. The puddle rotation speed is such that the entire front surface of the wafer W can be covered with the IPA liquid or the SPM liquid and is, for example, in a range of 30 to 300 rpm. In the first exemplary process, the puddle rotation speed is set, for example, to 60 rpm. Further, the controller 55 controls the organic solvent arm pivot mechanism 71 to move the organic solvent nozzle 5 to above the wafer W. Thus, the organic solvent nozzle 5 is located on the rotation axis C of the wafer W (in opposed relation to the rotation center of the wafer W) as shown in FIG. 9A.

The controller 55 opens the organic solvent valve 73 to spout the IPA liquid from the organic solvent nozzle 5 toward the front surface of the wafer W. At this time, the spouting flow rate of the IPA liquid is, for example, 0.6 (L/min).

Since the rotation speed of the wafer W is low, the IPA liquid supplied to the front surface of the wafer W is accumulated on the front surface of the wafer W to spread over the entire front surface of the wafer W. Thus, a liquid film 80 of the IPA liquid (organic solvent liquid film) is formed on the front surface of the wafer W as covering the entire front surface (Step S3: IPA liquid film forming step (organic solvent liquid film forming step)).

After a lapse of a predetermined IPA liquid spouting period from the start of the spouting of the IPA liquid, the controller 55 closes the organic solvent valve 73 to stop spouting the IPA liquid from the organic solvent nozzle 5, and controls the organic solvent arm pivot mechanism 71 to move the organic solvent nozzle 5 back to the home position after the spouting of the IPA liquid is stopped. The IPA liquid spouting period may be defined as a period required for forming the IPA liquid film 80 covering the entire front surface of the wafer W. For example, the IPA liquid spouting period is in a range of 3 to 10 seconds, e.g., 5 seconds, depending on the spouting flow rate of the IPA liquid and the puddle rotation speed.

Subsequently, the controller 55 controls the SPM liquid arm pivot mechanism 12 to move the SPM liquid nozzle 4 to above the wafer W to locate the SPM liquid nozzle 4 on the rotation axis C of the wafer W (in opposed relation to the rotation center of the wafer W) as shown in FIG. 9B.

Further, as shown in FIG. 9B, the controller 55 opens the sulfuric acid valve 18, the hydrogen peroxide solution valve 20 and the SPM liquid valve 23 to spout the SPM liquid from the SPM liquid nozzle 4. At this time, the spouting flow rate of the SPM liquid is, for example, 0.6 (L/min) (Step S4: SPM liquid supplying step (sulfuric acid-containing liquid supplying step)). Simultaneously with the IPA liquid supplying step of Step S4, the heater head 35 is moved from the home position defined on the lateral side of the wafer rotating mechanism 3 to above the middle adjacent position (indicated by the solid line in FIG. 5).

By thus spouting the SPM liquid from the SPM liquid nozzle 4, the SPM liquid is supplied to the front surface of the wafer W formed with the IPA liquid film 80. That is, the SPM liquid is supplied at a relatively low flow rate to the liquid film 80 formed of a relatively great amount of the IPA liquid. Thus, as shown in FIG. 9C, a liquid film 90 of a liquid mixture of the SPM liquid and the IPA liquid containing black particles 95 (hereinafter referred to as “SPM/IPA liquid mixture”) is formed on the front surface of the wafer W. In the liquid film 90 of the SPM/IPA liquid mixture, a dehydration reaction caused by the sulfuric acid in the SPM liquid proceeds. Therefore, the black particles 95 are precipitated in a great amount, so that the liquid film 90 is entirely black. The precipitated black particles 95 are black carbide particles mainly constituted by carbon. The mixing ratio between the SPM liquid and the IPA liquid in the liquid film 90 is, for example, approximately 10:1.

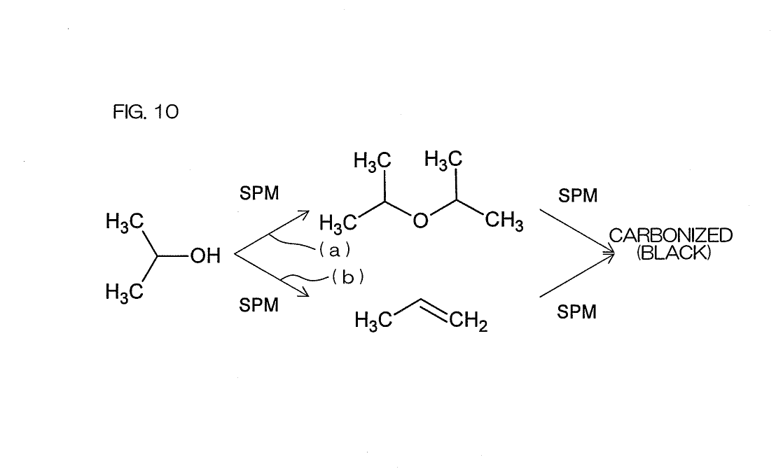

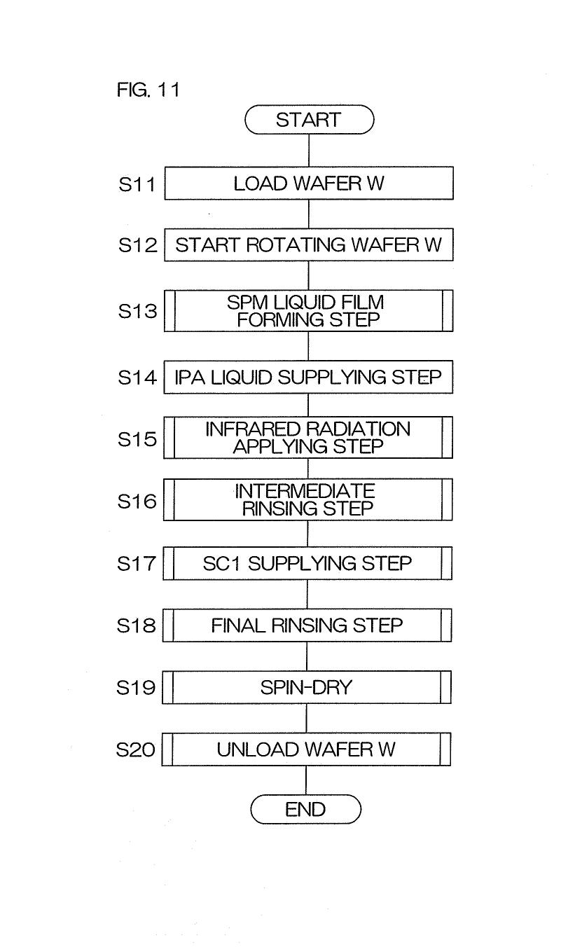

FIG. 10 is a diagram showing a black carbide generation mechanism. The black carbide particles are precipitated supposedly because of the following black carbide generation mechanism. The IPA liquid reacts with sulfuric acid in the SPM liquid, whereby the IPA liquid is dehydrated to generate an ether, an ester and the like. In FIG. 10, an arrow (a) indicates a reaction occurring when the temperature of the SPM liquid is lower (about 130° C. to about 140° C.), and an arrow (b) indicates a reaction occurring when the temperature of the SPM liquid is higher (about 160° C. to about 170° C.). The ether, the ester and the like as a reaction product are further carbonized by sulfuric acid in the SPM liquid, whereby black particles mainly formed of carbon are generated to be precipitated.

After a lapse of a predetermined SPM spouting period from the start of the spouting of the SPM liquid, the controller 55 closes the sulfuric acid valve 18, the hydrogen peroxide solution valve 20 and the SPM liquid valve 23 to stop spouting the SPM liquid from the SPM liquid nozzle 4, and controls the SPM liquid arm pivot mechanism 12 to move the SPM liquid nozzle 4 back to the home position after the spouting of the SPM liquid is stopped. The SPM liquid spouting period is such that the liquid film 90 of the SPM/IPA liquid mixture is formed on the wafer W as covering the entire front surface of the wafer W and the IPA liquid is not completely removed from the front surface of the wafer W. The SPM liquid spouting period is in a range of 3 to 10 seconds, e.g., 5 seconds, depending on the spouting flow rate of the SPM liquid to be spouted from the SPM liquid nozzle 4 and the puddle rotation speed.

The controller 55 controls the amplifier 54 to cause the infrared lamp 38 of the heater head 35 to emit infrared radiation, and controls the lift drive mechanism 37 to move the heater head 35 down from above the middle adjacent position (indicated by the solid line in FIG. 5) and locate the heater head 35 at the middle adjacent position. Thus, the front surface of the wafer W on which the liquid film 90 of the SPM/IPA liquid mixture is retained is irradiated with the infrared radiation emitted from the heater head 35 located in closely opposed relation to the front surface of the wafer W (Step S5: infrared radiation applying step).

As shown in FIG. 9D, the controller 55 controls the motor 6 to reduce the rotation speed of the wafer W to a liquid film retention rotation speed. The liquid film retention rotation speed is such that the liquid film 90 of the SPM/IPA liquid mixture can be retained on the front surface of the wafer W even without additional liquid supply (the supply of the SPM liquid) to the front surface of the wafer W (in a range of 1 to 30 rpm, e.g., 15 rpm). In the infrared radiation applying step of Step S5, the SPM liquid is not additionally supplied to the front surface of the wafer W, but the liquid film of the SPM/IPA liquid mixture is continuously retained on the front surface of the wafer W because the rotation speed of the wafer W is very low and virtually no centrifugal force acts on the SPM/IPA liquid mixture on the wafer W.

In the infrared radiation applying step of Step S5, as shown in FIG. 9D, a part of the liquid film 90 of the SPM/IPA liquid mixture present on a region of the wafer W opposed to the lower surface 52B of the heater head 35 is heated by the infrared radiation emitted from the infrared lamp 38. The infrared radiation applying step is performed for a predetermined infrared radiation applying period (in a range of 2 to 90 seconds, e.g., about 15 seconds).

In the infrared radiation applying step of Step S5, the liquid film 90 of the SPM/IPA liquid mixture and the wafer W are warmed by the infrared radiation emitted from the infrared lamp 38. In the infrared radiation applying step, a reaction between the resist present on the front surface of the wafer W and the SPM liquid contained in the liquid film 90 proceeds, whereby the resist is removed from the front surface of the wafer W.

In the infrared radiation applying step, as indicated by an arrow in FIG. 9D, the controller 55 controls the pivot drive mechanism 36 to reciprocally move the heater head 35 between the middle adjacent position (indicated by the solid line in FIG. 5) and the center adjacent position (indicated by the one-dot-and-dash line in FIG. 5). Thus, a part of the liquid film 90 of the SPM/IPA liquid mixture present on a region of the wafer W except for the center portion of the wafer W (inward of the radially intermediate portion of the wafer W) is entirely irradiated with the infrared radiation emitted from the heater head 35.

After a lapse of a predetermined infrared radiation applying period, the controller 55 controls the amplifier 54 to stop emitting the infrared radiation from the infrared lamp 38. Further, the controller 55 controls the pivot drive mechanism 36 and the lift drive mechanism 37 to move the heater head 35 back to the home position. Then, the controller 55 controls the motor 6 to increase the rotation speed of the wafer W to a predetermined liquid treatment rotation speed (in a range of 300 to 1500 rpm, e.g., 1000 rpm), and opens the rinse liquid valve 27 to supply the DIW from the outlet port of the rinse liquid nozzle 24 toward around the rotation center of the wafer W (Step S6: intermediate rinsing step). The DIW supplied to the front surface of the wafer W receives a centrifugal force generated by the rotation of the wafer W to flow toward the peripheral edge of the wafer W on the front surface of the wafer W. Thus, the SPM/IPA liquid mixture adhering to the front surface of the wafer W is rinsed away with the DIW.

After the supply of the DIW is continued for a predetermined intermediate rinsing period, the rinse liquid valve 27 is closed to stop supplying the DIW to the front surface of the wafer W.

While maintaining the rotation speed of the wafer W at the liquid treatment rotation speed, the controller 55 opens the SC1 valve 31 to supply the SC1 from the SC1 nozzle 25 to the front surface of the wafer W (Step S7: SC1 supplying step). Further, the controller 55 controls the SC1 arm drive mechanism 29 to pivot the SC1 arm 28 within the predetermined angular range to reciprocally move the SC1 nozzle 25 between the position above the rotation center of the wafer W and the position above the peripheral edge portion of the wafer W. Thus, the SC1 supply position to which the SC1 is supplied from the SC1 nozzle 25 on the front surface of the wafer W is reciprocally moved along an arcuate path crossing the wafer rotating direction within a range from the rotation center of the wafer W to the peripheral edge portion of the wafer W, whereby the SC1 is evenly supplied to the entire front surface of the wafer W. Thus, resist residue, particles and other foreign matter adhering to the front surface of the wafer W are removed by the chemical power of the SC1.

After the intermediate rinsing step of Step S6 is performed, black carbide particles 95 supposedly adhere to the front surface of the wafer W. If the wafer W is dried without cleaning the front surface of the wafer W, the black carbide particles may contaminate the wafer W. In the first exemplary process, however, the black carbide particles 95 adhering to the front surface of the wafer W are removed by the chemical power of the SC1 in the SC1 supplying step of Step S7.

After the supply of the SC1 is continued for a predetermined SC1 supplying period, the controller 55 closes the SC1 valve 31, and controls the SC1 arm pivot mechanism 29 to move the SC1 nozzle 25 back to the home position. While maintaining the rotation speed of the wafer W at the liquid treatment rotation speed, the controller 55 opens the rinse liquid valve 27 to supply the DIW from the outlet port of the rinse liquid nozzle 24 toward around the rotation center of the wafer W (Step S8: final rinsing step). The DIW supplied to the front surface of the wafer W receives a centrifugal force generated by the rotation of the wafer W to flow toward the peripheral edge of the wafer W on the front surface of the wafer W. Thus, the SC1 adhering to the front surface of the wafer W is rinsed away with the DIW.

After the supply of the DIW is continued for a predetermined rinsing period, the controller 55 closes the rinse liquid valve 27 to stop supplying the DIW to the front surface of the wafer W.

Thereafter, the controller 55 drives the motor 6 to increase the rotation speed of the wafer W to a predetermined higher rotation speed (e.g., 1500 to 2500 rpm). Thus, a spin drying step is performed to spun off the DIW adhering to the wafer W to dry the wafer W (Step S9). In the spin drying step of Step S9, the DIW adhering to the wafer W is removed from the wafer W. The rinse liquid to be used in the intermediate rinsing step of Step S6 and the final rinsing step of Step S8 is not limited to the DIW, but other examples of the rinse liquid include carbonated water, electrolytic ion water, ozone water, reduced water (hydrogen water) and magnetic water.

After the spin drying step is performed for a predetermined spin drying period, the controller 55 drives the motor 6 to stop the rotation of the wafer rotating mechanism 3. Thus, the resist removing process on the single wafer W is completed, and the treated wafer W is unloaded from the treatment chamber 2 by the transport robot (Step S10).

According to this embodiment, as described above, the liquid film 90 of the SPM/IPA liquid mixture is formed on the front surface of the wafer W. In the liquid film 90 of the SPM/IPA liquid mixture, the black carbide particles 95 are precipitated, so that the liquid film 90 is entirely black. The precipitated carbide particles 95 are mostly constituted by carbon and, therefore, have a very high infrared absorbance. Accordingly, the liquid film 90 of the SPM/IPA liquid mixture has a higher infrared absorbance and, hence, has a higher heating efficiency. With the liquid film 90 of the SPM/IPA liquid mixture thus formed on the front surface of the wafer W, therefore, the SPM/IPA liquid mixture containing the SPM liquid can be more advantageously warmed in the infrared radiation applying step of Step S5. This further increases the resist removing process efficiency, thereby reducing the process time for the entire resist removing process.

In this case, the SPM liquid is supplied to a greater amount of the IPA liquid and, therefore, the reaction occurring due to the contact and the mixing of the SPM liquid and the IPA liquid is moderate as compared with a case in which the IPA liquid is supplied to a greater amount of the SPM liquid. This prevents a violent reaction from occurring due to the contact and the mixing of the SPM liquid and the IPA liquid.

Even if the violent reaction occurs due to the contact and the mixing of the SPM liquid and the IPA liquid, the reaction does not occur within a pipe or the like but occurs on the front surface of the wafer W, because the SPM liquid and the IPA liquid are mixed together on the front surface of the wafer W. Therefore, the substrate treatment apparatus 1 is free from heavy damage.

Thus, it is possible to advantageously remove the resist from the front surface of the wafer W while reducing the consumption of the SPM liquid.

After the infrared radiation applying step of Step S5, the front surface of the wafer W is cleaned with the SC1. Thus, the black carbide particles can be completely removed from the front surface of the wafer W. As a result, occurrence of particles can be prevented after the wafer W is dried.

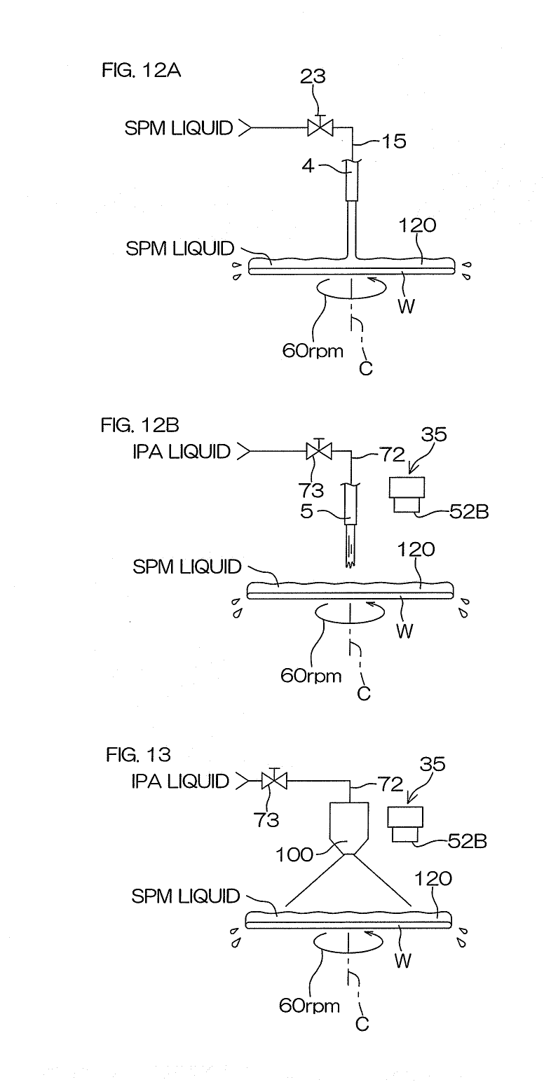

FIG. 11 is a process diagram for explaining a second exemplary resist removing process according to the present invention. FIGS. 12A and 12B are schematic diagrams for explaining an SPM liquid film forming step of Step S13 and an IPA liquid supplying step of Step S14.

The second exemplary resist removing process differs from the first exemplary process shown in FIG. 7 in that the SPM liquid film forming step (sulfuric acid-containing liquid film forming step) of Step S13 and the IPA liquid supplying step (organic solvent supplying step) of Step S14 are performed instead of the IPA liquid film forming step of Step S3 and the SPM liquid supplying step of Step S4.

Referring to FIGS. 1, 6, 7, 12A and 12B, the second exemplary resist removing process will be described.

In the second exemplary resist removing process, a wafer W not subjected to the ashing process is loaded into the apparatus (Step S11), and then the rotation of the wafer W is started (Step S12). As shown in FIG. 12A, the rotation speed of the wafer W is increased to a predetermined puddle rotation speed (e.g., 60 rpm). Further, the SPM liquid arm pivot mechanism 12 is controlled to locate the SPM liquid nozzle 4 on the rotation axis of the wafer W.

Then, as shown in FIG. 12A, the controller 55 opens the sulfuric acid valve 18, the hydrogen peroxide solution valve 20 and the SPM liquid valve 23 to spout the SPM liquid from the SPM liquid nozzle 4 toward the front surface of the wafer W (at a spouting flow rate of, for example, 0.6 (L/min)). Thus, a liquid film 120 of the SPM liquid is formed on the front surface of the wafer W as covering the entire front surface (Step S13: SPM liquid film forming step). After a lapse of a predetermined SPM liquid spouting period (in a range of 3 to 10 seconds, e.g., 5 seconds) from the start of the spouting of the SPM liquid, the spouting of the SPM liquid is stopped. Further, the SPM liquid arm pivot mechanism 12 is controlled to move the SPM liquid nozzle 4 to its home position after the spouting of the SPM liquid is stopped.

Subsequently, the controller 55 controls the organic solvent arm pivot mechanism 71 to move the organic solvent nozzle 5 to above the wafer W to locate the organic solvent nozzle 5 on the rotation axis C of the wafer W.

The controller 55 opens the organic solvent valve 73 to spout the IPA liquid from the organic solvent nozzle 5 (at a spouting flow rate of, for example, 0.6 (L/min) for an IPA liquid spouting period in a range of 3 to 10 seconds, e.g., 5 seconds) (Step S14: IPA liquid supplying step). Simultaneously with the IPA liquid supplying step of Step S14, the heater head 35 is moved from the home position defined on the lateral side of the wafer rotating mechanism 3 to above the middle adjacent position (indicated by the solid line in FIG. 5).

The IPA liquid is spouted from the organic solvent nozzle 5 to be supplied to the front surface of the wafer W on which the liquid film 120 of the SPM liquid is formed. Thus, a liquid film of the SPM/IPA liquid mixture containing black carbide particles 95 is formed on the front surface of the wafer W. The black carbide particles 95 are precipitated in a great amount in the SPM/IPA liquid mixture. After the spouting of the SPM liquid is stopped, the SPM liquid arm pivot mechanism 12 is controlled to move the SPM liquid nozzle 4 back to the home position.

After the spouting of the SPM liquid is stopped, the infrared radiation is emitted from the infrared lamp 38, and the heater head 35 is located at the middle adjacent position (indicated by the solid line in FIG. 5) (Step S15: infrared radiation applying step). In the infrared radiation applying step of Step S15, a part of the liquid film of the SPM/IPA liquid mixture present on a region of the wafer W opposed to the lower surface 52B of the heater head 35 is heated by the infrared radiation emitted from the infrared lamp 38. After a lapse of a predetermined infrared radiation applying period, the emission of the infrared radiation from the infrared lamp 38 is stopped, and the heater head 35 is moved back to the home position.

Then, the DIW is supplied from the rinse liquid nozzle 24 to the wafer W (Step S16: intermediate rinsing step). After the supply of the DIW is continued for a predetermined intermediate rinsing period, the supply of the DIW is stopped.

In turn, the SC1 is spouted from the SC1 nozzle 25 to the wafer W (Step S17: SC1 supplying step). The SC1 arm pivot mechanism 29 is controlled to pivot the SC1 arm 28 within the predetermined angular range. Thus, the SC1 nozzle 25 is reciprocally moved between the position defined on the rotation axis C of the wafer W and the position above the peripheral edge portion of the wafer W. After the supply of the SC1 is continued for a predetermined SC1 supplying period, the supply of the SC1 is stopped. Further, the SC1 nozzle 25 is moved back to the home position.

Subsequently, the DIW is supplied from the rinse liquid nozzle 24 to the wafer W (Step S18: final rinsing step). After the supply of the DIW is continued for a predetermined rinsing period, the supply of the DIW is stopped.

Thereafter, the rotation speed of the wafer W is increased to a predetermined higher rotation speed, whereby a spin drying step is performed to spin off the DIW adhering to the wafer W to dry the wafer W (Step S19). After the spin drying step ends, the rotation of the wafer rotating mechanism 3 is stopped, and the treated wafer W is unloaded from the treatment chamber 2 by the transport robot (Step S20).

Steps S11, S12, S15, S16, S17, S18, S19 and S20 described above are equivalent to Steps S1, S2, S5, S6, S7, S8, S9 and S10, respectively, in FIG. 7.

FIG. 13 is a schematic diagram showing a modification of the second exemplary process.

In FIG. 13, an organic solvent nozzle 100 which is a spray nozzle adapted to spray liquid droplets of the IPA liquid is provided instead of the organic solvent nozzle 5 defined by the straight nozzle (see FIG. 1). In this case, the IPA liquid droplets are sprayed from the organic solvent nozzle 100. For example, the IPA liquid droplets are sprayed onto the front surface of the wafer W with the liquid film 120 of the SPM liquid formed on the front surface of the wafer W. Thus, the IPA liquid droplets can be extensively and evenly supplied to the liquid film 120 of the SPM liquid. Since the IPA liquid droplets are minute liquid droplets, the reaction occurring due to the contact and the mixing of the SPM liquid and the IPA liquid is substantially prevented from becoming violent.

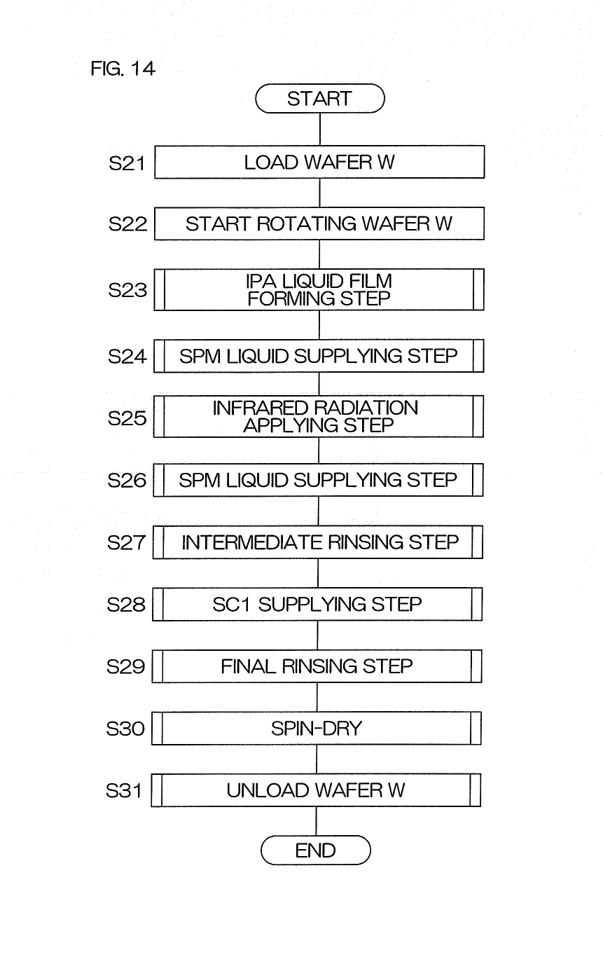

FIG. 14 is a process diagram for explaining a third exemplary resist removing process according to the present invention.

The third exemplary resist removing process differs from the first exemplary process shown in FIG. 7 in that a SPM liquid supplying step (Step S26) is additionally performed after an infrared radiation applying step of Step S25 to be described later. In the SPM liquid supplying step of Step S26, the rotation speed of the wafer W is increased to a predetermined liquid treatment rotation speed (e.g., 1000 rpm), and the SPM liquid nozzle 4 is located on the rotation axis C of the wafer W. Then, the sulfuric acid valve 18, the hydrogen peroxide solution valve 20 and the SPM liquid valve 23 are opened, whereby the SPM liquid is spouted from the SPM liquid nozzle 4 to be supplied to the front surface of the wafer W. Where the black carbide particles 95 (see FIG. 9C and the like) adhere to the front surface of the wafer W, the particles 95 are washed away with the SPM liquid.

In FIG. 14, Steps S21, S22, S23, S24, S25, S27, S28, S29, S30 and S31 are equivalent to Steps S1, S2, S3, S4, S5, S6, S7, S8, S9 and S10, respectively, shown in FIG. 7.

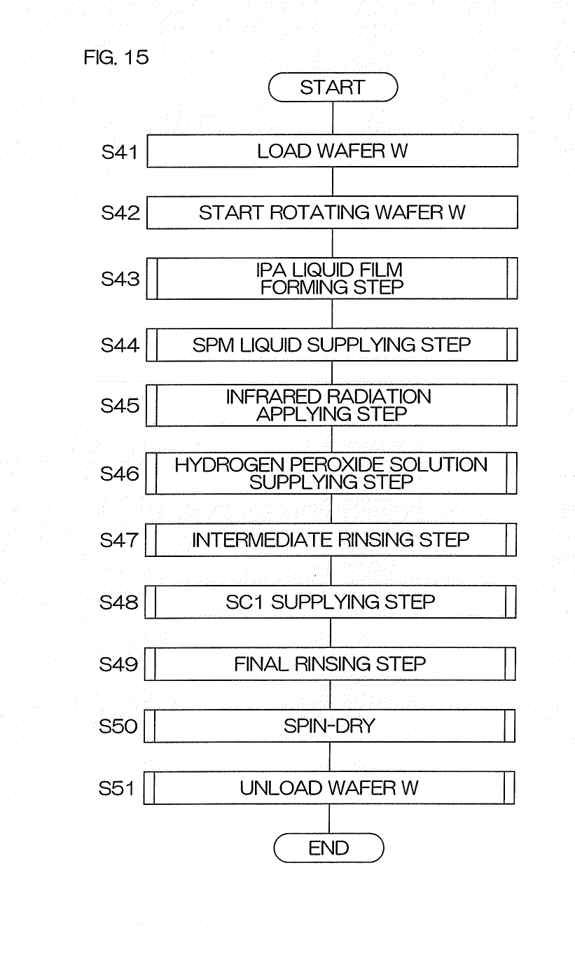

FIG. 15 is a process diagram for explaining a fourth exemplary resist removing process according to the present invention.

The fourth exemplary resist removing process differs from the first exemplary process shown in FIG. 7 in that a hydrogen peroxide solution supplying step (Step S46) is additionally performed after an infrared radiation applying step of Step S45 to be described later. In the hydrogen peroxide solution supplying step of Step S46, the rotation speed of the wafer W is increased to a predetermined liquid treatment rotation speed (e.g., 1000 rpm), and the SPM liquid nozzle 4 is located on the rotation axis C of the wafer W. Then, the SPM liquid valve 23 and the hydrogen peroxide solution valve 20 are opened with the sulfuric acid valve 18 closed, whereby the hydrogen peroxide solution is spouted from the SPM liquid nozzle 4 to be supplied to the front surface of the wafer W. Where black carbide particles 95 (see FIG. 9C and the like) adhere to the front surface of the wafer W, the particles 95 are washed away with the hydrogen peroxide solution.

In FIG. 15, Steps S41, S42, S43, S44, S45, S47, S48, S49, S50 and S51 are equivalent to Steps S1, S2, S3, S4, S5, S6, S7, S8, S9 and S10, respectively, shown in FIG. 7.

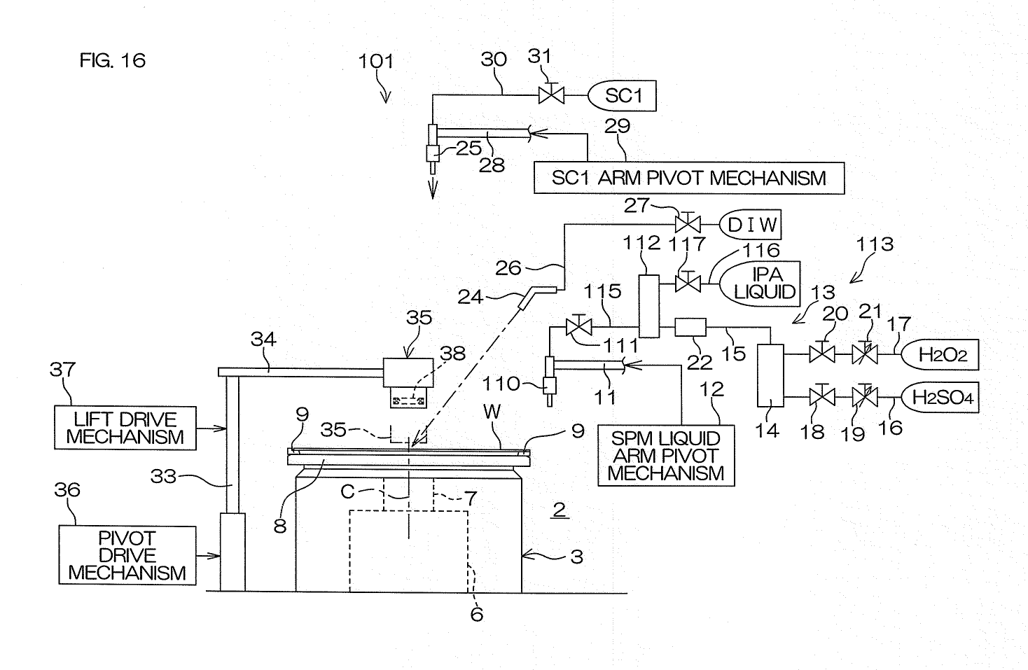

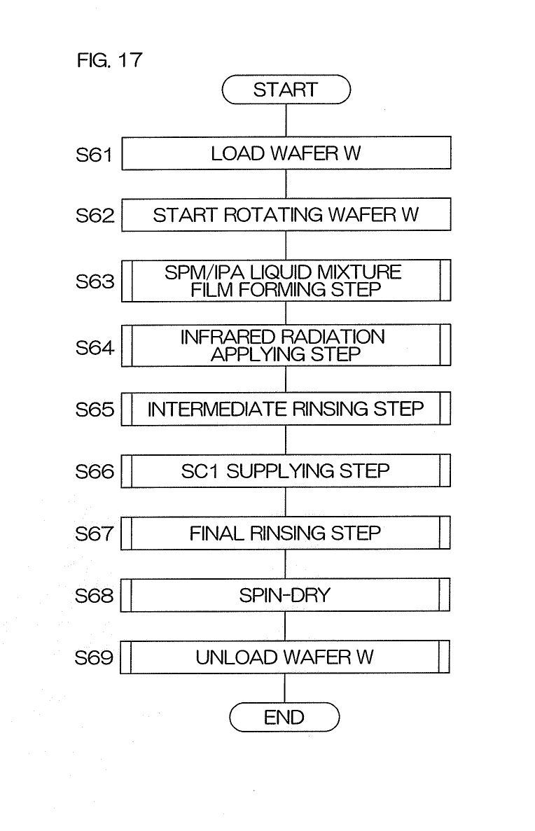

FIG. 16 is a diagram schematically showing the construction of a substrate treatment apparatus 101 according to another embodiment of the present invention. FIG. 17 is a process diagram for explaining an exemplary process to be performed by the substrate treatment apparatus 101.

In the embodiment shown in FIGS. 16 and 17, the substrate treatment apparatus 101 differs from the substrate treatment apparatus 1 shown in FIG. 1 and the like in that an SPM/IPA liquid mixture nozzle 110 is provided instead of the SPM liquid nozzle 4. In the embodiment shown in FIGS. 16 and 17, components equivalent to those shown in FIGS. 1 to 15 will be designated by the same reference characters as in FIGS. 1 to 15, and duplicate description will be omitted.

The SPM/IPA liquid mixture nozzle 110 is provided instead of the SPM liquid nozzle 4 at the distal end of the SPM liquid arm 11 with its outlet port directing downward. The SPM/IPA liquid mixture nozzle 110 is, for example, a straight nozzle which spouts the SPM/IPA liquid mixture in the form of a continuous stream. The SPM/IPA liquid mixture is supplied from an SPM/IPA liquid mixture supplying mechanism 113 to the SPM/IPA liquid mixture nozzle 110.

The SPM liquid supplying mechanism 113 which supplies the SPM liquid to the SPM/IPA liquid mixture nozzle 110 includes a second mixing portion 112, and an SPM/IPA liquid mixture supply pipe 115 connected between the second mixing portion 112 and the SPM/IPA liquid mixture nozzle 110. The SPM liquid supply pipe 15 of the SPM liquid supply mechanism 13 and an organic solvent supply pipe 116 are connected to the second mixing portion 112. An organic solvent valve 117 which opens and closes the organic solvent supply pipe 116 is provided in the organic solvent supply pipe 116. An SPM/IPA liquid mixture valve 111 which opens and closes the SPM/IPA liquid mixture supply pipe 115 is provided in the SPM/IPA liquid mixture supply pipe 115.

The IPA liquid is supplied from the organic solvent supply source to the second mixing portion 112 through the organic solvent supply pipe 116. The SPM/IPA liquid mixture valve 111 and the organic solvent valve 117, which are controlled by the controller 55 (see FIG. 6), are connected to the controller 55. The flow rate ratio between the SPM liquid to be supplied to the second mixing portion 112 through the SPM liquid supply pipe 15 and the IPA liquid to be supplied to the second mixing portion 112 through the organic solvent supply pipe 116 is approximately 10:1.

When the sulfuric acid valve 18, the hydrogen peroxide solution valve 20 and the organic solvent valve 117 are opened with the SPM/IPA liquid mixture valve 111 open, the SPM liquid supplied from the SPM liquid supply pipe 15 and the IPA liquid supplied from the organic solvent supply pipe 116 flow into the second mixing portion 112 to be mixed together in the second mixing portion 112 to provide the SPM/IPA liquid mixture. In the SPM/IPA liquid mixture, black carbide particles 95 are precipitated in a great amount, so that the SPM/IPA liquid mixture is entirely black. The SPM/IPA liquid mixture is supplied to the SPM/IPA liquid mixture nozzle 110 through the SPM/IPA liquid mixture supply pipe 115 to be spouted from the SPM/IPA liquid mixture nozzle 110.

In this exemplary resist removing process, a wafer W not subjected to the aching process is loaded into the apparatus (Step S61), and then the rotation of the wafer W is started (Step S62). The rotation speed of the wafer W is increased to a predetermined puddle rotation speed (e.g., 60 rpm), and the SPM liquid arm pivot mechanism 12 is controlled to locate the SPM/IPA liquid mixture nozzle 110 on the rotation axis C of the wafer W.

Then, the controller 55 (see FIG. 6) opens the sulfuric acid valve 18, the hydrogen peroxide solution valve 20, the IPA valve 117 and the SPM/IPA liquid mixture valve 111, whereby the SPM/IPA liquid mixture is spouted from the SPM/IPA liquid mixture nozzle 110 toward the front surface of the wafer W (at a spouting flow rate of, for example, 0.9 (L/min)) (Step S63: SPM/IPA liquid mixture film forming step). Simultaneously with the SPM/IPA liquid mixture film forming step of Step S63, the heater head 35 is moved from the home position defined on the lateral side of the wafer rotating mechanism 3 to above the middle adjacent position (indicated by the solid line in FIG. 5).

By thus spouting the SPM/IPA liquid mixture from the SPM/IPA liquid mixture nozzle 110, a liquid film of the SPM/IPA liquid mixture is formed on the front surface of the wafer W as covering the entire front surface. After a lapse of a predetermined SPM/IPA liquid mixture spouting period (in a range of 3 to 10 seconds, e.g., 5 seconds) from the start of the spouting of the SPM/IPA liquid mixture, the spouting of the SPM/IPA liquid mixture is stopped. Further, the SPM liquid arm pivot mechanism 12 is controlled to move the SPM/IPA liquid mixture nozzle 110 to its home position after the spouting of the SPM/IPA liquid mixture is stopped.

After the spouting of the SPM/IPA liquid mixture is stopped, the infrared radiation is emitted from the infrared lamp 38, and the heater head 35 is located at the middle adjacent position (indicated by the solid line in FIG. 5) (Step S64: infrared radiation applying step). After a lapse of a predetermined infrared radiation applying period, the emission of the infrared radiation from the infrared lamp 38 is stopped, and the heater head 35 is moved back to the home position.

Subsequently, the DIW is supplied from the rinse liquid nozzle 24 (Step S65: intermediate rinsing step). After the supply of the DIW is continued for a predetermined intermediate rinsing period, the supply of the DIW is stopped.

In turn, the SC1 is spouted from the SC1 nozzle 25 to the wafer W (Step S66: SC1 supplying step). The SC1 arm pivot mechanism 29 is controlled to pivot the SC1 arm 28 within the predetermined angular range. Thus, the SC1 nozzle 25 is reciprocally moved between the position defined above the rotation center of the wafer W and the position above the peripheral edge portion of the wafer W. After the supply of the SC1 is continued for a predetermined SC1 supplying period, the supply of the SC1 is stopped. Further, the SC1 nozzle 25 is moved back to the home position.

Subsequently, the DIW is supplied from the rinse liquid nozzle 24 to the wafer W (Step S67: final rinsing step). After the supply of the DIW is continued for a predetermined rinsing period, the supply of the DIW is stopped.

Thereafter, the rotation speed of the wafer W is increased to a predetermined higher rotation speed, whereby a spin drying step is performed to spin off the DIW adhering to the wafer W to dry the wafer W (Step S68). After the spin drying step ends, the rotation of the wafer rotating mechanism 3 is stopped, and the treated wafer W is unloaded from the treatment chamber 2 by the transport robot (Step S69).

Steps S61, S62, S64, S65, S66, S67, S68 and S69 described above are equivalent to Steps S1, S2, S5, S6, S7, S8, S9 and S10, respectively, in FIG. 7.

While the two embodiments of the present invention have thus been described, the invention may be embodied in other ways.

In the first embodiment, for example, the third exemplary process and the fourth exemplary process may each be combined with the second exemplary process. That is, the process may be performed by first forming the liquid film 120 of the SPM liquid (see FIG. 12A and the like) on the front surface of the wafer W, supplying the IPA liquid to the SPM liquid film 120 thus formed and, after the infrared radiation applying step, supplying the SPM liquid again to the front surface of the wafer W. Alternatively, the process may be performed by first forming the liquid film 120 of the SPM liquid on the front surface of the wafer W, supplying the IPA liquid to the SPM liquid film 120 thus formed and, after the infrared radiation applying step, supplying the hydrogen peroxide solution to the front surface of the wafer W.

The IPA liquid is used as the organic solvent by way of example but not by way of limitation, and other examples of the organic solvent include ethanol, acetone and other organic solvents which are carbonized by the dehydration and oxidation action of sulfuric acid.

In the first to fourth exemplary processes, the heater head 35 is reciprocally moved between the middle adjacent position (indicated by the solid line in FIG. 5) and the center adjacent position (indicated by the one-dot-and-dash line in FIG. 5), but may be moved between the edge adjacent position (indicated by the two-dot-and-dash line in FIG. 5) and the center adjacent position or between the middle adjacent position and the edge adjacent position.

The heater head 35 is not necessarily required to be reciprocally moved. The heater head 35 may be configured to stand still at the middle adjacent position, then be moved to the center adjacent position, and stand still at the center adjacent position (for intermittent movement) in the infrared radiation applying step. The intermittent movement of the heater head 35 is not limited to the movement between the middle adjacent position and the center adjacent position, but the heater head 35 may be moved between the middle adjacent position and the edge adjacent position or between the center adjacent position and the edge adjacent position.

The infrared lamp 38 includes a single annular lamp by way of example but not by way of limitation. The infrared lamp 38 may include a plurality of concentric annular lamps. Further, the infrared lamp 38 may include a plurality of linear lamps which are arranged parallel to each other in a horizontal plane.

The lamp housing 40 has a cylindrical shape, but may have a polygonal tubular shape (e.g., a rectangular tubular shape). In this case, the bottom plate 52 has a rectangular plate shape.

A disk-shaped or rectangular opposed plate having an opposed surface to be opposed to the front surface of the wafer W may be provided separately from the bottom plate 52 of the lamp housing 40. In this case, quartz may be used as a material for the opposed plate.

The SPM liquid is used as the sulfuric acid-containing liquid by way of example, but other examples of the sulfuric acid-containing liquid include sulfuric acid and sulfuric acid ozone liquid mixture.

In the exemplary processes described above, the SC1 supplying step is performed in Steps S7, S17, S28, S48 and S66 by way of example, but the SC1 supplying step may be obviated.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2012-188009 filed in the Japan Patent Office on Aug. 28, 2012, the disclosure of which is incorporated herein by reference in its entirety.

What is claimed is:

1. A substrate treatment method for removing a resist from a front surface of a substrate, the method comprising:
a liquid mixture film forming step of forming a liquid film of a liquid mixture of a sulfuric acid-containing liquid and an organic solvent on a front surface of a substrate held by a substrate holding unit; and
an infrared radiation applying step of providing a heater in opposed relation to the front surface of the substrate, and applying infrared radiation emitted from the heater to the front surface of the substrate on which the liquid film of the liquid mixture is retained.

2. The substrate treatment method according to claim 1, wherein the liquid mixture film forming step includes:
an organic solvent liquid film forming step of forming a liquid film of the organic solvent on the front surface of the substrate held by the substrate holding unit; and
a sulfuric acid-containing liquid supplying step of supplying the sulfuric acid-containing liquid to the front surface of the substrate retaining the liquid film of the organic solvent after the organic solvent liquid film forming step.

3. The substrate treatment method according to claim 1, wherein the liquid mixture film forming step includes:
a sulfuric acid-containing liquid film forming step of forming a liquid film of the sulfuric acid-containing liquid on the front surface of the substrate held by the substrate holding unit; and
an organic solvent supplying step of supplying the organic solvent to the front surface of the substrate retaining the liquid film of the sulfuric acid-containing liquid after the sulfuric acid-containing liquid film forming step.

4. The substrate treatment method according to claim 1, further comprising a cleaning step of cleaning the front surface of the substrate held by the substrate holding unit after the infrared radiation applying step.

5. A substrate treatment apparatus for removing a resist from a front surface of a substrate, the apparatus comprising:
a substrate holding unit which holds the substrate;
a liquid mixture supplying unit which supplies a liquid mixture of a sulfuric acid-containing liquid and an organic solvent to form a liquid film of the liquid mixture of the sulfuric acid-containing liquid and the organic solvent on the front surface of the substrate held by the substrate holding unit; and
a heater having an infrared lamp and provided in opposed relation to the front surface of the substrate held by the substrate holding unit to irradiate the front surface of the substrate with infrared radiation.

6. The substrate treatment apparatus according to claim 5, wherein the liquid mixture supplying unit includes:
a sulfuric acid-containing liquid nozzle which spouts the sulfuric acid-containing liquid to the front surface of the substrate held by the substrate holding unit; and
an organic solvent nozzle which spouts the organic solvent to the front surface of the substrate held by the substrate holding unit.

7. The substrate treatment apparatus according to claim 6, wherein the organic solvent nozzle is a spray nozzle which sprays liquid droplets of the organic solvent.

8. The substrate treatment apparatus according to claim 5, wherein the liquid mixture supplying unit includes a liquid mixture nozzle which spouts the liquid mixture of the sulfuric acid-containing liquid and the organic solvent to the front surface of the substrate held by the substrate holding unit.
